(19) United States
(12) Patent Application Publication
(10) Pub. No.: US 2025/0248512 A1
(43) Pub. Date: Aug. 7, 2025

(54) METHOD AND APPARATUS FOR ADJUSTING TILT OF BRUSH FOR CLEANING WAFER

(71) Applicant: KCTECH CO., LTD., Anseong-si (KR)

(72) Inventor: Ji Hoon Son, Hwaseong-si (KR)

(21) Appl. No.: 19/045,598

(22) Filed: Feb. 5, 2025

(30) Foreign Application Priority Data
Feb. 7, 2024 (KR) 10-2024-0018877

(51) Int. Cl. A46B 15/00; A46B 13/00; A46B 13/02; H01L 21/67

(52) U.S. Cl. CPC A46B 15/0004; A46B 13/001; A46B 13/02; H01L 21/67046; A46B 2200/3073

(57) ABSTRACT

Provided is a brush tilt adjustment apparatus. The brush tilt adjustment apparatus includes a wafer cleaner configured to clean a wafer using a brush, a sensor unit including acceleration sensors and a motor torque sensor mounted around the brush, a brush position adjuster including position adjustment motors configured to adjust a position of the brush in a vertical direction on both sides of the brush, and a processing unit configured to detect a position value of each side of the brush and configured to estimate a tilt of the brush, in which the brush position adjuster is configured to adjust the position of the brush based on at least one of the estimated tilt of the brush and the position value.

### CROSS-REFERENCE TO RELATED APPLICATIONS

This application claims the benefit of Korean Patent Application No. 10-2024-0018877, filed on Feb. 7, 2024, in the Korean Intellectual Property Office, the entire disclosure of which is incorporated herein by reference for all purposes.

### FIELD OF THE INVENTION

The following disclosure relates to technology of adjusting a tilt of a brush for cleaning a wafer.

### BACKGROUND

A brush may contact a wafer at various tilts and clean the wafer during a process of cleaning the wafer using the brush. Accordingly, the tilt of a brush may need to be adjusted so that the tilt of the brush corresponds to a target tilt each time the brush cleans a wafer. The technique according to the related art derives a tilt direction in which a brush contacts a wafer based on the difference between a standard amplitude of a normal vibration frequency and an amplitude of a measured vibration frequency. However, the technique according to the related art is limited to estimating the tilt of a brush and has difficulty in accurately measuring the tilt of the brush. Therefore, research is needed to complement the limitation of the technique according to the related art.

### SUMMARY

According to an aspect, there is provided an apparatus for adjusting a tilt of a brush for cleaning a wafer, the apparatus including a wafer cleaner configured to clean the wafer using the brush, a sensor unit including acceleration sensors and a motor torque sensor mounted around the brush, a brush position adjuster including position adjustment motors configured to adjust a position of the brush in a vertical direction on both sides of the brush, and a processing unit configured to detect a position value of each side of the brush and configured to estimate a tilt of the brush, in which the brush position adjuster is configured to adjust the position of the brush based on at least one of the estimated tilt of the brush and the position value.

The processing unit may be configured to recognize a point in time when a rotation torque value of a rotation motor rotating the brush, which is measured by the motor torque sensor, satisfies a preset condition, detect the position value of each side of the brush at the point in time when the rotation torque value satisfies the preset condition, and estimate the tilt of the brush based on a point in time when an amplitude of a movement value, measured by the acceleration sensors, satisfies the preset condition.

The position adjustment motors may include a first position adjustment motor provided on a first side of the brush and a second position adjustment motor provided on a second side of the brush.

The acceleration sensors may include a first acceleration sensor provided on a first side of the brush and a second acceleration sensor provided on a second side of the brush.

The processing unit may be configured to estimate the tilt of the brush based on a difference between a point in time when an amplitude of a movement value, measured by a first acceleration sensor, satisfies a preset condition and a point in time when an amplitude of a movement value, measured by a second acceleration sensor, satisfies the preset condition.

The brush position adjuster may be configured to adjust the position of the brush so that the brush contacts the wafer at a preset target tilt.

The processing unit may be configured to recognize a point in time when a rotation torque value becomes greater than or equal to a preset threshold value as a point in time when the rotation torque value satisfies a preset condition.

The processing unit may be configured to recognize a point in time when an amplitude of a movement value, measured by the acceleration sensors, becomes greater than or equal to a preset threshold value as a point in time when the amplitude of the movement value, measured by the acceleration sensors, satisfies a preset condition.

The processing unit may be configured to recognize, as a point in time when the brush contacts the wafer, at least one of a point in time when a rotation torque value satisfies a preset condition and a point in time when an amplitude of a movement value satisfies the preset condition.

According to another aspect, there is provided a method of adjusting a tilt of a brush for cleaning a wafer, the method including measuring at least one of a rotation torque value of a rotation motor, which rotates the brush, by using a motor torque sensor and an amplitude of a movement value of the brush by using acceleration sensors, detecting a position value of each side of the brush and estimating the tilt of the brush based on at least one of the rotation torque value and the amplitude of the movement value, and adjusting a position of the brush based on at least one of the estimated tilt of the brush and the position value.

The estimating of the tilt of the brush may include recognizing a point in time when the rotation torque value of the rotation motor rotating the brush, which is measured by the motor torque sensor, satisfies a preset condition and detecting the position value of each side of the brush at the point in time when the rotation torque value satisfies the preset condition and estimating the tilt of the brush based on a point in time when the amplitude of the movement value, measured by the acceleration sensors, satisfies the preset condition.

The method may further include cleaning the wafer using the brush.

The method may further include adjusting the position of the brush in a vertical direction on both sides of the brush by using position adjustment motors, in which the position adjustment motors may include a first position adjustment motor provided on a first side of the brush and a second position adjustment motor provided on a second side of the brush.

The acceleration sensors may include a first acceleration sensor provided on a first side of the brush and a second acceleration sensor provided on a second side of the brush.

The estimating of the tilt of the brush may include estimating the tilt of the brush based on a difference between a point in time when an amplitude of a movement value, measured by a first acceleration sensor, satisfies a preset condition and a point in time when an amplitude of a movement value, measured by a second acceleration sensor, satisfies the preset condition.

The adjusting of the position of the brush may include adjusting the position of the brush so that the brush contacts the wafer at a preset target tilt.

A point in time when the rotation torque value satisfies a preset condition may be a point in time when the rotation torque value becomes greater than or equal to a preset threshold value.

A point in time when the amplitude of the movement value, measured by the acceleration sensors, satisfies a preset condition may be a point in time when the amplitude of the movement value, measured by the acceleration sensors, becomes greater than or equal to a preset threshold value.

At least one of a point in time when the rotation torque value satisfies a preset condition and a point in time when the amplitude of the movement value satisfies the preset condition may be a point in time when the brush contacts the wafer.

Additional aspects of embodiments will be set forth in part in the description which follows and, in part, will be apparent from the description, or may be learned by practice of the disclosure.

According to embodiments, a current tilt of a brush for cleaning a wafer may be accurately estimated.

According to embodiments, a tilt of a brush for cleaning a wafer may be adjusted to a target tilt.

According to embodiments, a brush may properly clean a wafer at an accurate tilt by adjusting a tilt of the brush to a target tilt.

According to embodiments, a brush may clean a wafer at an accurate tilt even when the brush is worn.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram illustrating an outline of a brush tilt adjustment apparatus, according to an embodiment;

FIG. 2 is a flowchart illustrating a brush tilt adjustment method according to an embodiment;

FIGS. 3 to 6 are diagrams illustrating a point in time when a brush contacts a wafer, according to an embodiment; and

FIG. 7 is a diagram illustrating a configuration of a brush tilt adjustment apparatus, according to an embodiment.

### DETAILED DESCRIPTION

The following detailed structural or functional description is provided as an example only and various alterations and modifications may be made to embodiments. Accordingly, the embodiments are not to be construed as limited to the disclosure and should be understood to include all changes, equivalents, or replacements within the idea and the technical scope of the disclosure.

Although terms, such as first, second, and the like are used to describe various components, the components are not limited to the terms. These terms should be used only to distinguish one component from another component. For example, a first component may be referred to as a second component, and similarly the second component may also be referred to as the first component.

It should be noted that if it is described that one component is “connected”, “coupled”, or “joined” to another component, a third component may be “connected”, “coupled”, and “joined” between the first and second components, although the first component may be directly connected, coupled, or joined to the second component.

The singular forms “a”, “an”, and “the” are intended to include the plural forms as well, unless the context clearly indicates otherwise. As used herein, “A or B”, “at least one of A and B”, “at least one of A or B”, “A, B or C”, “at least one of A, B and C”, and “at least one of A, B, or C,” each of which may include any one of the items listed together in the corresponding one of the phrases, or all possible combinations thereof. It will be further understood that the terms “comprises/comprising” and/or “includes/including,” when used herein, specify the presence of stated features, integers, steps, operations, elements, and/or components, but do not preclude the presence or addition of one or more other features, integers, steps, operations, elements, components and/or groups thereof.

Unless otherwise defined, all terms used herein including technical or scientific terms have the same meaning as commonly understood by one of ordinary skill in the art to which this disclosure pertains. Terms, such as those defined in commonly used dictionaries, should be construed to have meanings matching with contextual meanings in the relevant art, and are not to be construed to have an ideal or excessively formal meaning unless otherwise defined herein.

As used in connection with the present disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more of functions. For example, according to an embodiment, the module may be implemented in a form of an application-specific integrated circuit (ASIC).

The term “unit” used herein may refer to a software or hardware component, such as a field-programmable gate array (FPGA) or an ASIC, and the “unit” performs predefined functions. However, the term “unit” is not limited to software or hardware. A “unit” may be configured to be in an addressable storage medium or configured to operate one or more processors. Accordingly, the “unit” may include, for example, components, such as software components, object-oriented software components, class components, and task components, processes, functions, attributes, procedures, sub-routines, segments of program code, drivers, firmware, microcode, circuitry, data, databases, data structures, tables, arrays, and variables. The functionalities provided in the components and “units” may be combined into fewer components and “units” or may be further separated into additional components and “units.” Furthermore, the components and “units” may be implemented to operate one or more of central processing units (CPUs) within a device or a security multimedia card. In addition, “unit” may include one or more of processors.

Hereinafter, embodiments will be described in detail with reference to the accompanying drawings. When describing the embodiments with reference to the accompanying drawings, like reference numerals refer to like elements and a repeated description related thereto will be omitted.

A brush tilt adjustment apparatus described herein may perform a brush tilt adjustment method of estimating a tilt that a brush for cleaning a wafer contacts the wafer by removing particles remaining on the wafer after polishing the wafer in a chemical mechanical polishing (CMP) process and adjusting the tilt of the brush. The brush may clean the wafer at various angles for each wafer or each cleaning process. In some cases, it may be necessary to adjust the tilt of the brush because the brush (more specifically, the bristles of the brush) may be worn due to the cleaning process so that the initially set tilt and the actual tilt that the brush contacts the wafer may be different. The brush tilt adjustment apparatus described herein may perform a brush tilt adjustment method of estimating a tilt (more specifically, a current tilt) of the brush so that the brush may accurately contact the wafer and clean the wafer at a predetermined tilt and adjusting the position of the brush so that the tilt of the brush becomes a target tilt based on the current tilt. Position adjustment motors may be mounted on each end of the brush to adjust the position of the brush. The position adjustment motors may adjust the tilt of the brush by moving the position of the brush in the vertical direction by different degrees on each end of the brush.

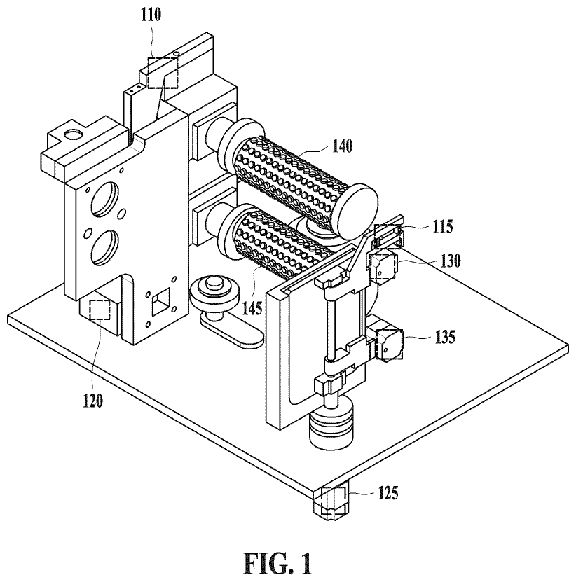

FIG. 1 is a diagram illustrating an outline of a brush tilt adjustment apparatus, according to an embodiment.

Referring to FIG. 1, the brush tilt adjustment apparatus may include at least two brushes 140 and 145. A wafer may be introduced between the two brushes 140 and 145, and the brushes 140 and 145 may clean the wafer by narrowing the gap between each other. Acceleration sensors 110 and 115 may be disposed on both sides of the brushes 140 and 145, respectively. More specifically, the acceleration sensors 110 and 115 may be disposed on both fixing portions of the brushes 140 and 145, respectively. The acceleration sensors 110 and 115 may measure a movement value of the brushes 140 and 145 from the brushes 140 and 145. Torque sensors 130 and 135 of a motor may measure a rotation torque value of the motor that rotates the brushes 140 and 145 and may each be disposed on one side of the brushes 140 and 145. The tilt of the brushes 140 and 145 and the gap between the brushes 140 and 145 may be adjusted by the motor to move the brushes 140 and 145 in the vertical direction, that is, in the up-and-down direction. The gap between the brushes 140 and 145 may be narrowed while cleaning the wafer, and the gap between the brushes 140 and 145 may be widened while not cleaning the wafer. The wafer may be cleaned by being positioned between the brushes 140 and 145 while the gap between the brushes 140 and 145 is narrowed. Position value sensors 120 and 125 may measure a position value (a pulse value) of the motor that moves the brushes 140 and 145 in the vertical direction. The brush tilt adjustment apparatus may detect the position value and tilt of the brushes 140 and 145 based on the position value of the motor that moves the brushes 140 and 145 in the vertical direction.

The brush tilt adjustment apparatus may estimate the tilt of the brushes 140 and 145 based on the difference (the time difference) between points in time when both sides of the brushes 140 and 145 contact the wafer. The brush tilt adjustment apparatus may adjust the position of the brushes 140 and 145 based on at least one of the position value of each side of the brushes 140 and 145, the estimated tilt of the brushes 140 and 145, and a preset target tilt. The brush tilt adjustment apparatus may adjust the brushes 140 and 145 to be tilted by the preset target tilt by adjusting the position of the brushes 140 and 145 using position adjustment motors.

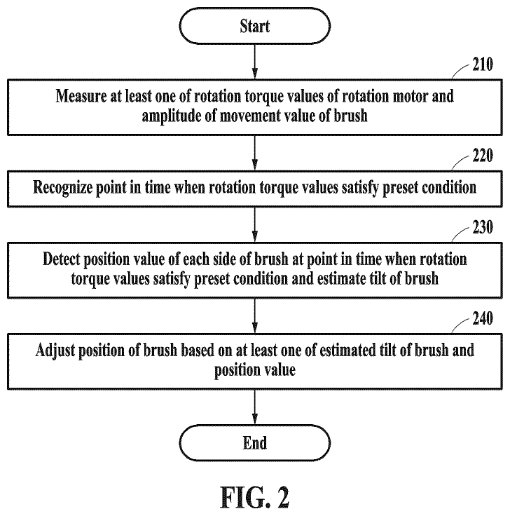

FIG. 2 is a flowchart illustrating a brush tilt adjustment method according to an embodiment.

A brush tilt adjustment apparatus may clean a wafer using a brush. FIG. 2 illustrates a flowchart illustrating the brush tilt adjustment method of adjusting the tilt of the brush for cleaning the wafer, according to an embodiment. Referring to FIG. 2, in operation 210, the brush tilt adjustment apparatus may measure at least one of rotation torque values of a rotation motor that rotates the brush using a motor torque sensor and an amplitude of a movement value of the brush using acceleration sensors. At least one of the motor torque sensor and the acceleration sensors may be provided in the brush tilt adjustment apparatus. Here, the movement value may also be referred to as a vibration value.

The brush tilt adjustment apparatus may detect a position value of each side of the brush and estimate the tilt of the brush based on at least one of the measured rotation torque values and the measured amplitude of the movement value. In this process, the brush tilt adjustment apparatus may perform operations 220 and 230. In operation 220, the brush tilt adjustment apparatus may recognize a point in time when the rotation torque values of the rotation motor rotating the brush, which are measured by the motor torque sensor, satisfy a preset condition. Here, the point in time when the rotation torque values satisfy the preset condition may be a point in time when the rotation torque values become greater than or equal to a preset threshold value. That is, the brush tilt adjustment apparatus may recognize the point in time when the rotation torque values become greater than or equal to the preset threshold value as a point in time when the brush contacts the wafer. The brush tilt adjustment apparatus may perform data preprocessing by performing a moving average on the rotation torque values. In operation 230, the brush tilt adjustment apparatus may detect the position value of each side of the brush at the point in time when the rotation torque values satisfy the preset condition and may estimate the tilt of the brush based on the point in time when the amplitude of the movement value, measured by the acceleration sensors, satisfies the preset condition. The brush tilt adjustment apparatus may detect the position value of each side of the brush at the point in time when the brush contacts the wafer. The position value may also be referred to as a vertical position value and may be a position value of the brush or a position value of at least one of position adjustment motors. The acceleration sensors may include a first acceleration sensor provided on a first side of the brush and a second acceleration sensor provided on a second side of the brush. Here, the first side of the brush may represent the front or front side of the brush, and the second side of the brush may represent the rear or rear side of the brush, but embodiments are not limited thereto. In addition, when the first side of the brush is the front of the brush, the second side of the brush may represent the rear of the brush, and when the first side of the brush is the rear of the brush, the second side of the brush may represent the front of the brush. Additionally, when the first side of the brush is the left side of the brush, the second side of the brush may represent the right side of the brush, and when the first side of the brush is the right side of the brush, the second side of the brush may represent the left side of the brush.

The brush tilt adjustment apparatus may estimate the tilt of the brush based on the difference between a point in time when an amplitude of a movement value, measured by the first acceleration sensor, satisfies a preset condition and a point in time when an amplitude of a movement value, measured by the second acceleration sensor, satisfies the preset condition. The point in time when the amplitude of the movement value, measured by the acceleration sensors, satisfies the preset condition may be the point in time when the amplitude of the movement value, measured by the acceleration sensors, becomes greater than or equal to a preset threshold value. Accordingly, the brush tilt adjustment apparatus may estimate the tilt of the brush based on the difference between a point in time when the amplitude of the movement value, measured by the first acceleration sensor, becomes greater than or equal to the preset threshold value and a point in time when the amplitude of the movement value, measured by the second acceleration sensor, becomes greater than or equal to the preset threshold value. The point in time when the amplitude of the movement value satisfies the preset condition and the point in time when the amplitude of the movement value becomes greater than or equal to the preset threshold value may be the point in time when the brush contacts the wafer. The brush tilt adjustment apparatus may estimate the tilt of the brush based on the difference between a point in time when the first side of the brush provided with the first acceleration sensor contacts the wafer and a point in time when the second side of the brush provided with the second acceleration sensor contacts the wafer. That is, the brush tilt adjustment apparatus may estimate the tilt of the brush in the manner described above based on the premise that the points in time when each side of the brush contacts the wafer differ depending on the tilt of the brush. Here, the tilt estimated by the brush tilt adjustment apparatus may also be referred to as a current tilt and may represent the degree to which the brush is currently tilted. For example, the brush tilt adjustment apparatus may estimate the tilt of the brush as 0 when the difference between the point in time when the first side of the brush provided with the first acceleration sensor contacts the wafer and the point in time when the second side of the brush provided with the second acceleration sensor contacts the wafer is 0. The brush tilt adjustment apparatus may also estimate the absolute value of the tilt of the brush in proportion to the absolute value of the difference between the point in time when the first side of the brush provided with the first acceleration sensor contacts the wafer and the point in time when the second side of the brush provided with the second acceleration sensor contacts the wafer.

In operation 240, the brush tilt adjustment apparatus may adjust the position of the brush based on at least one of the estimated tilt of the brush and the position value. The brush tilt adjustment apparatus may adjust, using the position adjustment motors, the position of the brush in the vertical direction on both sides of the brush. The brush tilt adjustment apparatus may calculate a moving distance for the brush to reach the wafer based on at least one of the estimated tilt of the brush and the position value. The brush tilt adjustment apparatus may adjust the position of the brush based on at least one of the estimated tilt of the brush, the calculated moving distance, and the position value.

Here, both sides may refer to both the first side and the second side, and the first side may refer to one side of the brush and the second side may refer to the other side that is opposite to the first side.

The position adjustment motors may include a first position adjustment motor provided on the first side of the brush and a second position adjustment motor provided on the second side of the brush. The first position adjustment motor may adjust the position of the first side of the brush, and the second position adjustment motor may adjust the position of the second side of the brush. The brush tilt adjustment apparatus may adjust the position of the brush so that the brush contacts the wafer at a preset target tilt. The brush tilt adjustment apparatus may adjust the current tilt of the brush to the target tilt based on the difference between the degree to which the first position adjustment motor adjusts the position of the brush and the degree to which the second position adjustment motor adjusts the position of the brush. Here, the target tilt may refer to a tilt for the brush to adjust the tilt from the current tilt. That is, the target tilt may refer to the target degree of the tilt in which the brush should be tilted.

In another embodiment, the brush tilt adjustment apparatus may determine that the brush is worn when the estimated tilt is not the same as the target tilt based on the difference between the point in time when the amplitude of the movement value, measured by the first acceleration sensor, satisfies the preset condition and the point in time when the amplitude of the movement value, measured by the second acceleration sensor, satisfies the preset condition after the position of the brush is adjusted based on the target tilt. In this case, the brush tilt adjustment apparatus may cause the brush to contact the wafer at a predetermined tilt and clean the wafer even though the brush is worn by resetting the target tilt.

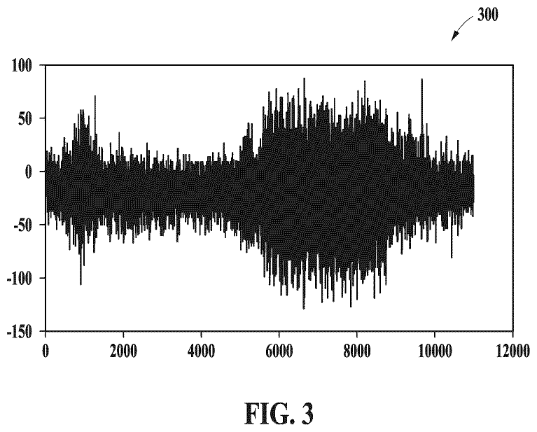

FIGS. 3 to 6 are diagrams illustrating a point in time when a brush contacts a wafer, according to an embodiment.

FIG. 3 illustrates a graph 300 before an acceleration sensor measurement value measured by acceleration sensors including at least one of a first acceleration sensor and a second acceleration sensor is processed. FIG. 3 illustrates the graph 300 before the acceleration sensor measurement value is processed. That is, FIG. 3 illustrates the graph 300 before the acceleration sensor measurement value is data preprocessed. Referring to the graph 300, it may be seen that there is a point in time when the acceleration sensor measurement value starts to increase and a point in time when the acceleration sensor measurement value starts to decrease. The acceleration sensor measurement value may increase because the movement increases when a brush contacts a wafer. Accordingly, the point in time when the acceleration sensor measurement value increases may correspond to the point in time when the brush contacts the wafer. Here, the acceleration sensor measurement value may be referred to as at least one of an acceleration value and an acceleration sensor signal value.

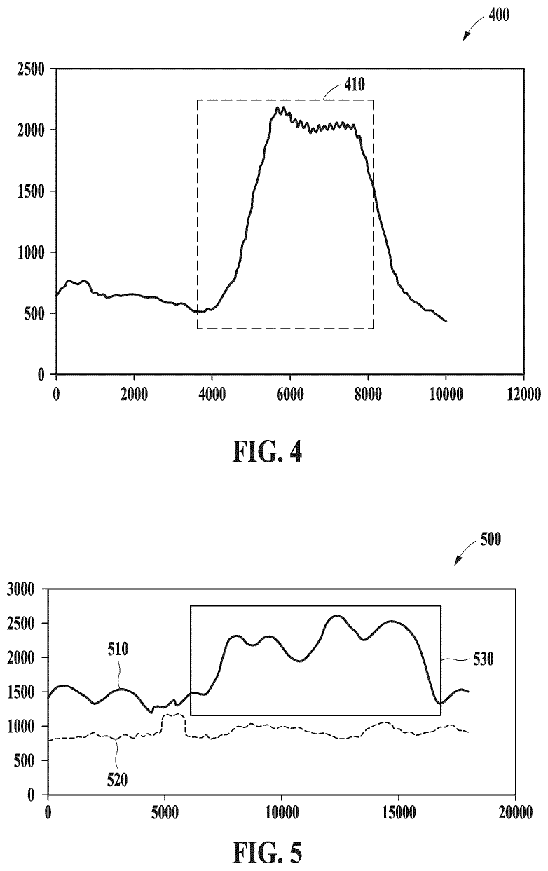

FIG. 4 illustrates a graph 400 representing acceleration sensor measurement values on which data preprocessing is performed. A brush tilt adjustment apparatus may perform data preprocessing by performing a square and a moving average on the acceleration sensor measurement values. FIG. 4 illustrates the graph 400 representing the acceleration sensor measurement values on which the square and the moving average are performed. Reference numeral 410 may correspond to a point in time when the acceleration sensor measurement values are greater than or equal to a preset threshold value and may correspond to a point in time when the brush is in contact with the wafer. That is, a state in which the brush is in contact with the wafer may continue for a period corresponding to the reference numeral 410. The first point in time of the reference numeral 410 may correspond to the point in time when the brush contacts the wafer.

Data preprocessing may be performed on the acceleration sensor measurement values by being squared and then moving-averaged. The moving average may be performed as shown in Equation 1 below.

$$\begin{matrix}{\overline{p}}_{SM} = \frac{{p}_{M} + {p}_{M - 1} + … + {p}_{M - ( n - 1 )}}{n} \\ = \frac{1}{n} {\sum }_{i = 0}^{n - 1} {p}_{M - i} .\end{matrix} \qquad [ Equation 1 ]$$

Here, p̅_{SM} denotes a moving-averaged value and p_{M}, p_{M-1}, p_{M-(n-1)}, and p_{M-i} denote values to be moving-averaged.

FIG. 5 illustrates a graph 500 representing an amplitude of a movement value. Referring to FIG. 5, reference numeral 510 may represent an amplitude of a movement value of a first side of a brush, and reference numeral 520 may represent an amplitude of a movement value of a second side of the brush. Reference numeral 530 may represent an amplitude of a movement value while the first side of the brush is in contact with a wafer and the second side of the brush is not in contact with the wafer. The first point in time of the reference numeral 530 may correspond to a point in time when an amplitude of a movement value, measured by a first acceleration sensor of the first side of the brush, becomes greater than or equal to a preset threshold value.

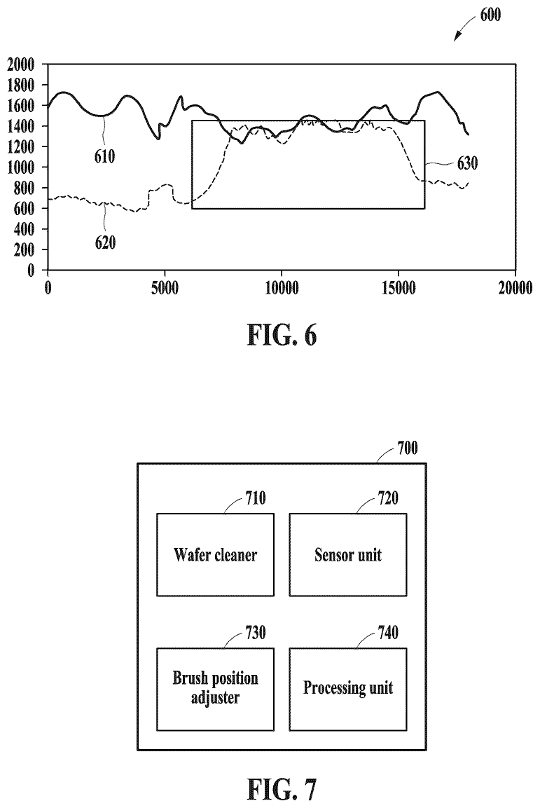

FIG. 6 illustrates a graph 600 representing an amplitude of a movement value. Referring to FIG. 6, reference numeral 610 may represent an amplitude of a movement value of a first side of a brush, and reference numeral 620 may represent an amplitude of a movement value of a second side of the brush. Reference numeral 630 may represent an amplitude of a movement value while the second side of the brush is in contact with a wafer and the first side of the brush is not in contact with the wafer. The first point in time of the reference numeral 630 may correspond to a point in time when an amplitude of a movement value, measured by a second acceleration sensor of the second side of the brush, becomes greater than or equal to a preset threshold value.

FIG. 7 is a diagram illustrating a configuration of a brush tilt adjustment apparatus, according to an embodiment.

A brush tilt adjustment apparatus 700 may include a wafer cleaner 710, a sensor unit 720, a brush position adjuster 730, and a processing unit 740. The brush tilt adjustment apparatus 700 may correspond to the brush tilt adjustment apparatus described herein.

The wafer cleaner 710 may include a brush and clean a wafer using the brush. The wafer cleaner 710 may include, for example, at least two brushes but is not limited thereto.

The sensor unit 720 may include a sensor circuit, and the sensor circuit may include acceleration sensors and a motor torque sensor mounted around the brush. The sensor unit 720 may include a position value sensor configured to measure a position value of each side of the brush. The position value sensor may measure a position value of the brush or measure position values of position adjustment motors that move the brush in the vertical direction. The position value described herein may represent the position value of the brush or represent the position values of the position adjustment motors that move the brush in the vertical direction. The sensor unit 720 may further include a sensor that is provided in the brush tilt adjustment apparatus 700 and measures sensing data or measurement values, but embodiments are not limited thereto.

The brush position adjuster 730 may include the position adjustment motors configured to adjust the position of the brush in the vertical direction on both sides of the brush. The brush position adjuster 730 may adjust the position of the brush based on at least one of the estimated tilt of the brush and the position value. The brush position adjuster 730 may adjust the position of the brush so that the brush contacts the wafer at a preset target tilt.

The processing unit 740 may detect the position value of each side of the brush and estimate the tilt of the brush. The processing unit 740 may recognize a point in time when a rotation torque value of a rotation motor rotating the brush, which is measured by the motor torque sensor, satisfies a preset condition, detect the position value of each side of the brush at the point in time when the rotation torque value satisfies the preset condition, and estimate the tilt of the brush based on a point in time when an amplitude of a movement value, measured by the acceleration sensors, satisfies the preset condition. The processing unit 740 may estimate the tilt of the brush based on the difference between a point in time when an amplitude of a movement value, measured by a first acceleration sensor, satisfies the preset condition and a point in time when an amplitude of a movement value, measured by a second acceleration sensor, satisfies the preset condition. The processing unit 740 may recognize a point in time when the rotation torque value becomes greater than or equal to a preset threshold value as a point in time when the rotation torque value satisfies the preset condition. The processing unit 740 may recognize the point in time when the amplitude of the movement value, measured by the acceleration sensors, becomes greater than or equal to the preset threshold value as the point in time when the amplitude of the movement value, measured by the acceleration sensors, satisfies the preset condition. The processing unit 740 may recognize, as a point in time when the brush contacts the wafer, at least one of the point in time when the rotation torque value satisfies the preset condition and the point in time when the amplitude of the movement value satisfies the preset condition.

The processing unit 740 may include a memory (not shown) and a processor (not shown), and the processor may perform operations of the processing unit 740. The memory may store instructions that the processor may perform. The memory may include a separate device such as an external disk drive, a storage array, or other storage devices usable by a database system. The memory and the processor may be operatively connected or may communicate through, for example, an input/output (I/O) port or a network connection, so that the processor may read a file stored in the memory. The memory may be a non-transitory computer-readable storage medium that stores instructions, and the instructions stored in the memory, when executed by the processor, may cause the brush tilt adjustment apparatus 700 to perform one or more operations of the brush tilt adjustment apparatus described herein.

The non-transitory computer-readable storage medium may include read-only memory (ROM), programmable ROM (PROM), electrically erasable PROM (EEPROM), random-access memory (RAM), dynamic RAM (DRAM), static RAM (SRAM), flash memory, non-volatile memory, a compact disc (CD), a digital video disk (DVD), BLU-RAY or optical disk memory, a hard disk drive (HDD), a solid state drive (SSD), card memory (e.g., a multimedia card, a secure digital (SD) card, or an extreme digital (XD) card), magnetic tape, a floppy disk, a magneto-optical data storage device, an optical data storage device, a hard disk, a solid state drive (SSD), and other devices.

The processor may execute the instructions stored in the memory. The processor may include a central processing unit (CPU), a graphics processing unit (GPU), a neural network processing unit (NPU), a media processing unit (MPU), a data processing unit (DPU), a vision processing unit (VPU), a video processor, an image processor, a display processor, a microprocessor, a processor core, a multi-core processor, an application-specific integrated circuit (ASIC), a field programmable gate array (FPGA), or any combination thereof.

The brush position adjuster 730 may adjust the position of the brush that is tilted at the tilt estimated by the processing unit 740 so that the brush contacts the wafer at a preset target tilt.

The units described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, an FPGA, a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciate that a processing device may include multiple processing elements and/or multiple types of processing elements. For example, the processing device may include a plurality of processors, or a single processor and a single controller. In addition, different processing configurations are possible, such as parallel processors.

Software may include a computer program, a piece of code, an instruction, or some combination thereof, to independently or collectively instruct or configure the processing device to operate as desired. Software and/or data may be embodied permanently or temporarily in any type of machine, component, physical or virtual equipment, or computer storage medium or device capable of providing instructions or data to or being interpreted by the processing device. The software may also be distributed over network-coupled computer systems so that the software is stored and executed in a distributed fashion. The software and data may be stored in a non-transitory computer-readable recording medium.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher-level code that may be executed by the computer using an interpreter.

The above-described hardware devices may be configured to act as one or more software modules in order to perform the operations of the above-described embodiments, or vice versa.

As described above, although the embodiments have been described with reference to the limited drawings, a person skilled in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

1. An apparatus for adjusting a tilt of a brush for cleaning a wafer, the apparatus comprising:
a wafer cleaner configured to clean the wafer using the brush;
a sensor unit comprising acceleration sensors and a motor torque sensor mounted around the brush;
a brush position adjuster comprising position adjustment motors configured to adjust a position of the brush in a vertical direction on both sides of the brush; and
a processing unit configured to detect a position value of each side of the brush and configured to estimate the tilt of the brush,
wherein the brush position adjuster is configured to adjust the position of the brush based on at least one of the estimated tilt of the brush and the position value.

2. The apparatus of claim 1, wherein the processing unit is configured to recognize a point in time when a rotation torque value of a rotation motor rotating the brush, which is measured by the motor torque sensor, satisfies a preset condition, detect the position value of each side of the brush at the point in time when the rotation torque value satisfies the preset condition, and estimate the tilt of the brush based on a point in time when an amplitude of a movement value, measured by the acceleration sensors, satisfies the preset condition.

3. The apparatus of claim 1, wherein the position adjustment motors comprise:
a first position adjustment motor provided on a first side of the brush; and
a second position adjustment motor provided on a second side of the brush.

4. The apparatus of claim 1, wherein the acceleration sensors comprise:
a first acceleration sensor provided on a first side of the brush; and
a second acceleration sensor provided on a second side of the brush.

5. The apparatus of claim 1, wherein the processing unit is configured to estimate the tilt of the brush based on a difference between a point in time when an amplitude of a movement value, measured by a first acceleration sensor, satisfies a preset condition and a point in time when an amplitude of a movement value, measured by a second acceleration sensor, satisfies the preset condition.

6. The apparatus of claim 1, wherein the brush position adjuster is configured to adjust the position of the brush so that the brush contacts the wafer at a preset target tilt.

7. The apparatus of claim 1, wherein the processing unit is configured to recognize a point in time when a rotation torque value becomes greater than or equal to a preset threshold value as a point in time when the rotation torque value satisfies a preset condition.

8. The apparatus of claim 1, wherein the processing unit is configured to recognize a point in time when an amplitude of a movement value, measured by the acceleration sensors, becomes greater than or equal to a preset threshold value as a point in time when the amplitude of the movement value, measured by the acceleration sensors, satisfies a preset condition.

9. The apparatus of claim 1, wherein the processing unit is configured to recognize, as a point in time when the brush contacts the wafer, at least one of a point in time when a rotation torque value satisfies a preset condition and a point in time when an amplitude of a movement value satisfies the preset condition.

10. A method of adjusting a tilt of a brush for cleaning a wafer, the method comprising:
measuring at least one of a rotation torque value of a rotation motor, which rotates the brush, by using a motor torque sensor and an amplitude of a movement value of the brush by using acceleration sensors;
detecting a position value of each side of the brush and estimating the tilt of the brush based on at least one of the rotation torque value and the amplitude of the movement value; and
adjusting a position of the brush based on at least one of the estimated tilt of the brush and the position value.

11. The method of claim 10, wherein the estimating of the tilt of the brush comprises:
recognizing a point in time when the rotation torque value of the rotation motor rotating the brush, which is measured by the motor torque sensor, satisfies a preset condition; and
detecting the position value of each side of the brush at the point in time when the rotation torque value satisfies the preset condition and estimating the tilt of the brush based on a point in time when the amplitude of the movement value, measured by the acceleration sensors, satisfies the preset condition.

12. The method of claim 10, further comprising:
cleaning the wafer using the brush.

13. The method of claim 10, further comprising:
adjusting the position of the brush in a vertical direction on both sides of the brush using position adjustment motors,
wherein the position adjustment motors comprise:
a first position adjustment motor provided on a first side of the brush; and
a second position adjustment motor provided on a second side of the brush.

14. The method of claim 10, wherein the acceleration sensors comprise:
a first acceleration sensor provided on a first side of the brush; and
a second acceleration sensor provided on a second side of the brush.

15. The method of claim 10, wherein the estimating of the tilt of the brush comprises estimating the tilt of the brush based on a difference between a point in time when an amplitude of a movement value, measured by a first acceleration sensor, satisfies a preset condition and a point in time when an amplitude of a movement value, measured by a second acceleration sensor, satisfies the preset condition.

16. The method of claim 10, wherein the adjusting of the position of the brush comprises adjusting the position of the brush so that the brush contacts the wafer at a preset target tilt.

17. The method of claim 10, wherein a point in time when the rotation torque value satisfies a preset condition is a point in time when the rotation torque value becomes greater than or equal to a preset threshold value.

18. The method of claim 10, wherein a point in time when the amplitude of the movement value, measured by the acceleration sensors, satisfies a preset condition is a point in time when the amplitude of the movement value, measured by the acceleration sensors, becomes greater than or equal to a preset threshold value.

19. The method of claim 10, wherein at least one of a point in time when the rotation torque value satisfies a preset condition and a point in time when the amplitude of the movement value satisfies the preset condition is a point in time when the brush contacts the wafer.

20. A non-transitory computer-readable storage medium storing instructions that, when executed by a processor, cause the processor to perform the method of claim 10.
